(19) United States
(12) Patent Application Publication
(10) Pub. No.: US 2024/0304591 A1
(43) Pub. Date: Sep. 12, 2024

(54) SEMICONDUCTOR DEVICE FOR AUDIO

(71) Applicant: ROHM CO., LTD., KYOTO-SHI (JP)

(72) Inventor: YOSUKE SATO, KYOTO-SHI (JP)

(21) Appl. No.: 18/594,605

(22) Filed: Mar. 4, 2024

(30) Foreign Application Priority Data
Mar. 7, 2023 (JP) 2023-034699

(51) Int. Cl. H01L 23/00; G06F 3/16; H01L 23/495

(52) U.S. Cl. CPC H01L 24/49; H01L 24/48; H01L 2224/45144; H01L 2224/45147; H01L 2224/48245; H01L 2224/4903; H01L 2224/49505

(57) ABSTRACT

The present disclosure provides a semiconductor device for audio. The semiconductor device for audio includes: a semiconductor element having a plurality of electrodes; a plurality of leads; and a plurality of wires, electrically connecting the plurality of electrodes to the plurality of leads. The plurality of wires include: a first wire having a main component of a first metal; and a second wire having a main component of a second metal different from the first metal.

### TECHNICAL FIELD

The present disclosure relates to a semiconductor device for audio.

### BACKGROUND

Semiconductor devices having semiconductor elements are extensively applied. As a semiconductor element, a semiconductor element formed by an integrated circuit (IC) or a large-scale integration (LSI) is used in various purposes. Patent document 1 discloses an example of a semiconductor device, which is configured as a semiconductor device for audio including a semiconductor element for audio, a plurality of leads, a plurality of conducting wires, and a sealing resin. The plurality of conducting wires conductively connect a plurality of electrodes of the semiconductor element with a plurality of wires.

### PRIOR ART DOCUMENT

### Patent Publication

[Patent document 1] Japan Patent Publication No. 2022-17498

### BRIEF DESCRIPTION OF THE DRAWINGS

FIG. 1 is a perspective diagram of a semiconductor device according to a first embodiment of the present disclosure.

FIG. 2 is a perspective diagram of a semiconductor device according to the first embodiment of the present disclosure.

FIG. 3 is a plan view of a semiconductor device according to the first embodiment of the present disclosure.

FIG. 4 is a block diagram of a semiconductor element of the semiconductor device according to the first embodiment of the present disclosure.

FIG. 5 is a plan view of a semiconductor device according to a second embodiment of the present disclosure.

FIG. 6 is a plan view of a semiconductor device of a first comparison example.

FIG. 7 is a plan view of a semiconductor device of a second comparison example.

FIG. 8 is a plan view of a semiconductor device of a third comparison example.

FIG. 9 is a table of evaluation results of a semiconductor device.

### DETAILED DESCRIPTION OF THE EMBODIMENTS

Details of the preferred embodiments of the present disclosure are specifically described with the accompanying drawings below.

The terms “first”, “second” and “third” used in the present disclosure are for identification purposes, and are not intended for assigning orders to the targets.

In the present disclosure, expressions “an object A formed at an object B” and “an object A formed on/over an object B” include “an object A directly formed at an object B”, and “another object placed between an object A and an object B, and the object A formed at the object B”, unless otherwise specified. Similarly, expressions “an object A arranged at an object B” and “an object A arranged on/over an object B” include “an object A directly arranged at an object B”, and “another object placed between an object A and an object B, and the object A arranged at the object B”, unless otherwise specified. Similarly, an expression “an object A located on an object B” includes “an object A in contact with an object B, the object A located on/over the object B”, and “another object placed between an object A and an object B, and the object A located on/over the object B”, unless otherwise specified. Moreover, an expression “an object A overlapping an object B when viewed in a direction” includes “an object A completely overlapping an object B” and “an object A partially overlapping an object B”, unless otherwise specified. Moreover, in the present disclosure, an expression “a surface A facing (one side or the other side of) a direction B” is not only limited to being a situation where the surface A being at an angle of 90° relative to the direction B, but also includes a situation where the surface A is inclined relative to the direction B.

FIGS. 1 to 5 show a semiconductor device for audio according to a first embodiment of the present disclosure. A semiconductor device A1 for audio of this embodiment includes a semiconductor element 1 for audio, a plurality of leads 2, a plurality of wires 3, and a plurality of sealing resins 4. The semiconductor device A1 for audio is not defined to have a specific package structure, and a quad flat package (QFP) shown in the drawing is merely an example. The semiconductor device A1 for audio is not defined to have specific functions or purposes. For example, the semiconductor device A1 for audio is an audio digital/analog (D/A) converter or an operational amplifier (OA). In the description below, the semiconductor device A1 for audio configured as an audio D/A converter is provided as an example.

The semiconductor element 1 for audio is a key element that practices main functions of the semiconductor device A1 for audio. The semiconductor element 1 for audio is configured as an integrated circuit (IC) or a large-scale integration (LSI). In general, the functions of the semiconductor element 1 for audio determine the purpose of the semiconductor device A1 for audio. In this embodiment, the semiconductor element 1 for audio has a rectangular shape in a plan view.

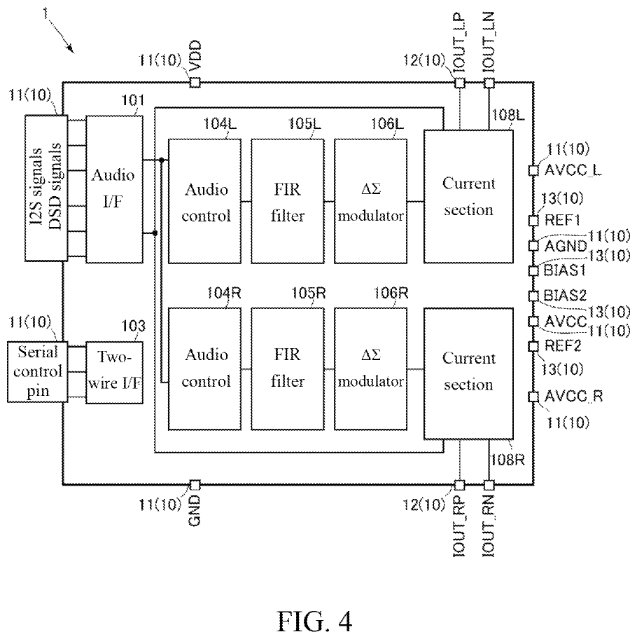

FIG. 4 shows an example of a block diagram of the semiconductor element 1 for audio of the semiconductor device A1 for audio that functions as an audio D/A converter. In the example shown in the drawing, the semiconductor element 1 for audio includes interface units 101 and 103, control units 104L and 104R, filter units 105L and 105R, modulators 106L and 106R, and current section units 108L and 108R.

The interface units 101 and 103 are blocks for input digital signals. The interface unit 101 is, for example, an interface used for digital signals of a pulse code modulation (PCM) scheme (PCM digital signals). An input sampling frequency is, for example, 32 kHz to 768 kHz, and an input data bit length is, for example, 16-bit to 32-bit. Moreover, the interface unit 101 is, for example, an interface used for digital signals of a direct stream digital (DSD) scheme (DSD digital signals). A sampling frequency is, for example, 2.8 MHz, 5.6 MHz, 11.2 MHz or 22.4 MHz.

The interface unit 103 is, for example, a register-controlled two-wire interface. A communication speed is, for example, 400 KHz.

When the semiconductor device A1 for audio is implemented as a stereo-sound audio D/A converter, the control unit 104L, the filter unit 105L and the modulator 106L are blocks that process audio signals of a left channel, and the control unit 104R, the filter unit 105R and the modulator 106R are blocks that process audio signals of a right channel.

The control units 104L and 104R control a digital audio format. For example, the control units 104L and 104R perform LR exchange, stereo/mono switching and phase inversion on PCM digital signals.

The filter units 105L and 105R are, for example, finite impulse response (FIR) filters, and can be appropriately selected to be filters having functions such as sharp roll off/slow roll off.

The modulators 106L and 106R perform, for example, pulse modulation, for example, ΔΣ(δ−Σ) modulation.

The current section units 108L and 108R output analog signals for the left channel and the right channel.

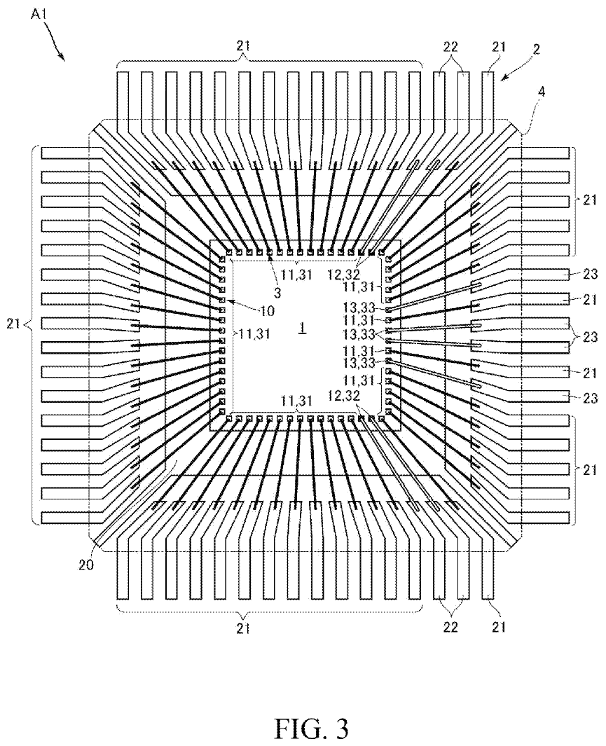

As shown in FIG. 3, the semiconductor element 1 for audio includes a plurality of electrodes 10. In this embodiment, the plurality of electrodes 10 are disposed on a single surface of the semiconductor element 1 for audio. The plurality of electrodes 10 are arranged along four sides around the semiconductor element 1 for audio.

The plurality of electrodes 10 include a plurality of first electrodes 11, a plurality of second electrodes 12 and a plurality of third electrodes 13.

The plurality of first electrodes 11 include electrodes arranged on the left side in FIG. 4. These first electrodes 11 are collectively referred to as, for example, connectors of “Inter-IC sound (I2S) signals”, Direct Stream Digital (DSD) signals”, or are referred to as electrodes of connectors of a serial control pin and are electrodes for digital signal inputs.

Moreover, the plurality of first electrodes 11 include electrodes arranged on the upper side and the lower side in FIG. 4. These first electrodes 11 are referred to as, for example, electrodes for “VDD” and “GND”, and are electrodes for digital power supplies.

Moreover, the plurality of first electrodes 11 include electrodes arranged on the right side in FIG. 4. These first electrodes 11 are referred to as, for example, electrodes for “AVCC_L”, “AVCC_R”, “AGND” and “AVCC”, and are electrodes for analog power supplies.

The plurality of second electrodes 12 include electrodes arranged on the upper side and the lower side in FIG. 4. These second electrodes 12 are referred to as, for example, “IOUT_LP”, “IOUT_LN”, “IOUT_RP” and “IOUT_RN”, and are electrodes for analog signal outputs.

The plurality of third electrodes 13 include electrodes arranged on the right side in FIG. 4. These third electrodes 13 are referred to as, for example, electrodes for “REF1”, “REF2”, “BIAS1”, and “BIAS2”.

The plurality of leads 2 are conducted with the plurality of electrodes 10 of the semiconductor element 1 for audio, and are used when the semiconductor device Al for audio is installed on such as a circuit board (omitted from the drawing) of an audio apparatus. The material of the leads 2 is not specifically defined, and includes, for example, copper (Cu), nickel (Ni), iron (Fe) or an alloy thereof, as a main component. In this embodiment, the plurality of leads 2 include a center lead 20, a plurality of first leads 21, a plurality of second leads 22 and a plurality of third leads 23.

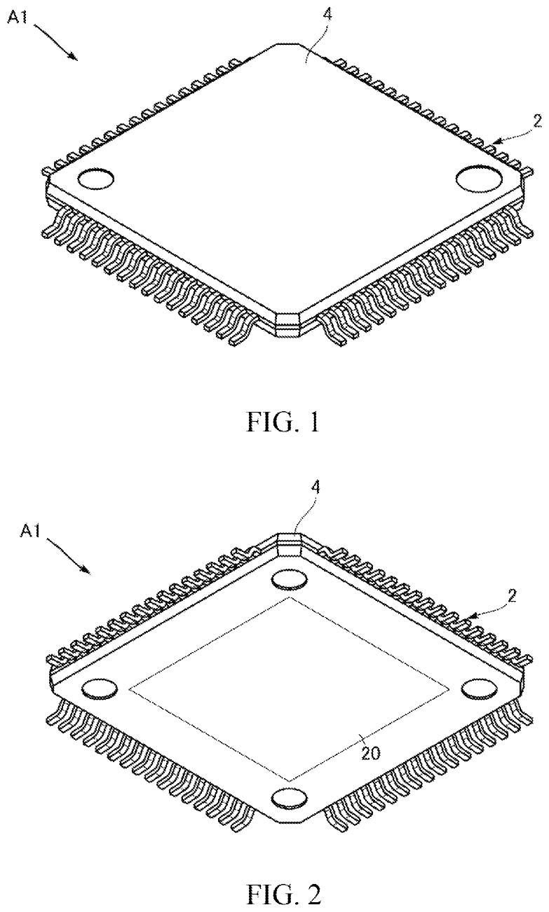

The center lead 20 is mounted with the semiconductor element 1 for audio. In the example shown in the drawing, as shown in FIG. 2, the center lead 20 is exposed from the sealing resin 4, but is not limited to such configuration.

The plurality of first leads 21, the plurality of second leads 22 and the plurality of third leads 23 protrude from around the sealing resin 4 in the plan view. The plurality of first leads 21 are separately conductively connected with the plurality of first electrodes 11 by a plurality of wires 3 (wires 31 described below). The plurality of second leads 22 are separately conductively connected with the plurality of second electrodes 12 by a plurality of wires 3 (wires 32 described below). The plurality of third leads 23 are separately conductively connected with the plurality of third electrodes 13 by a plurality of wires 3 (wires 33 described below).

The plurality of wires 3 conductively connect the plurality of first electrodes 11 of the semiconductor element 1 for audio with the plurality of leads 2. The wires 3 include a metal, for example, Cu, gold (Au), aluminum (Al), silver (Ag), Fe or an alloy thereof as a main component. In this embodiment, the plurality of wires 3 include the plurality of wires 31, the plurality of wires 32 and the plurality of wires 33.

The plurality of wires 31 are separately connected to the plurality of first electrodes 11 and the plurality of first leads 21. In this embodiment, the wires 31 include Cu as a main component.

The plurality of wires 32 are separately connected to the plurality of second electrodes 12 and the plurality of second leads 22. The plurality of wires 33 are separately connected to the plurality of third electrodes 13 and the plurality of third leads 23. In this embodiment, the plurality of wires 32 and 33 include Au as a main component. In addition, line diameters and lengths of the wires 3 are appropriate set. In this embodiment, the line diameters of the plurality of wires 3 can be the same. Moreover, the lengths of the plurality of wires 3 can be the same.

In this embodiment, the wires 31 are equivalent to “the first wires” of the present disclosure, and Cu is an example of a first metal of the present disclosure. The wires 32 and the wires 33 are equivalent to “the second wires” of the present disclosure, and Au is an example of a second metal of the present disclosure. Au which is an example of the second metal is softer than Cu which is an example of the first metal. Moreover, Cu which is an example of the first metal has an electrical resistivity less than that of Au which is an example of the second metal. In FIG. 3, black lines represent the first wires, and white lines with black borders represent the second wires. The same applies to the drawings below.

The sealing resin 4 covers the semiconductor element 1 for audio, a portion of each of the plurality of leads 2, and the plurality of wires 3. The sealing resin 4 is not defined to be formed of a specific material, and is formed of, for example, black epoxy blended with a filler. The sealing resin 4 is not defined to have a specific shape, and has, for example, a rectangular shape in the plan view.

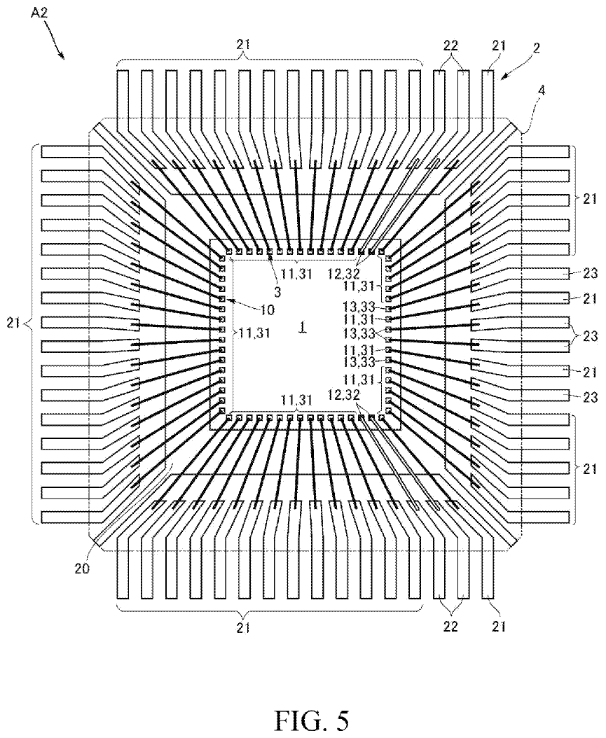

Next, FIG. 5 shows a semiconductor device for audio according to a second embodiment of the present disclosure. A semiconductor device A2 for audio of this embodiment differs from the semiconductor device A1 for audio in terms of setting the plurality of wires 33 as the first wires of the present disclosure. That is to say, the plurality of wires 33 of this embodiment include Cu, which is an example of the first metal, as the main component.

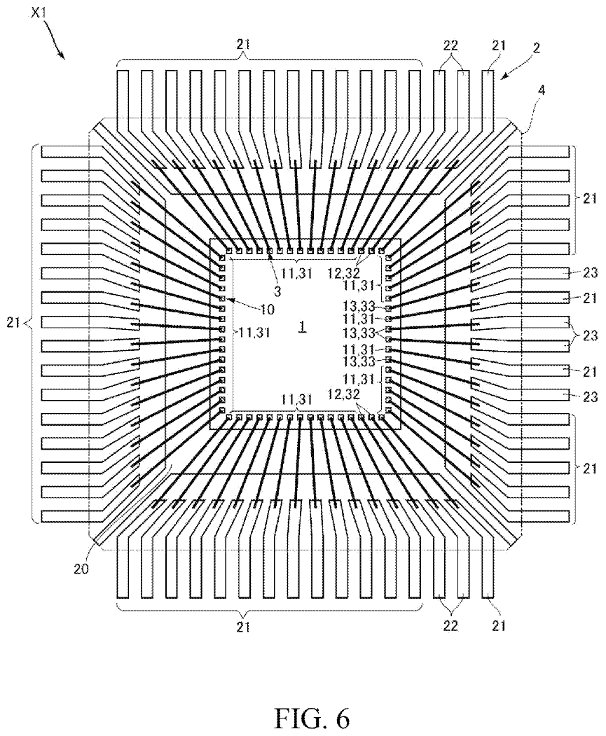

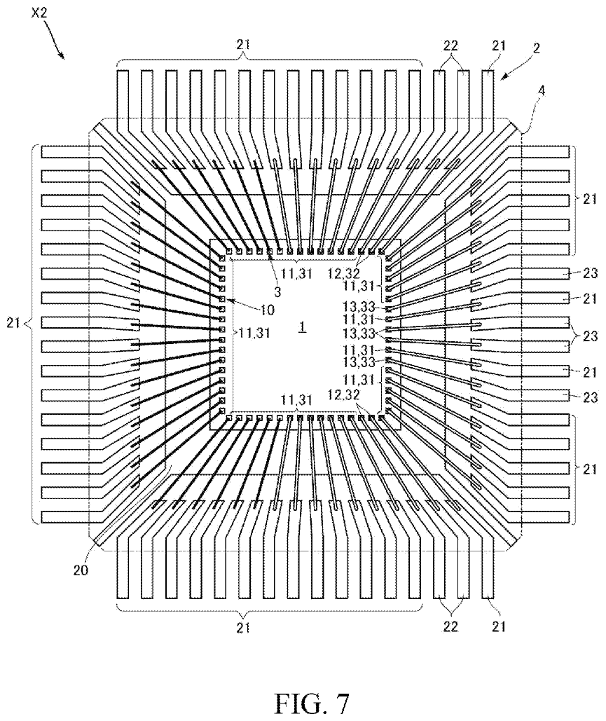

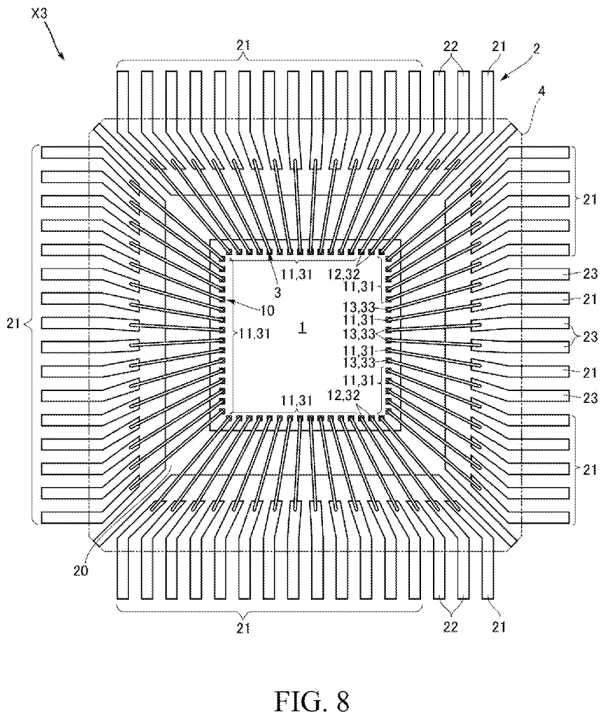

Next, FIG. 6 to FIG. 8 show comparison examples of semiconductor devices for audio. In a semiconductor device X1 for audio of the first comparison example shown in FIG. 6, all of the wires 3 include Cu, which is an example of the first metal, as the main component. In a semiconductor device X2 for audio of the second comparison example shown in FIG. 7, a portion of the plurality of wires 31, the plurality of wires 32 and the plurality of wires 33 include Au, which is an example of the second metal, as the main component. In a semiconductor device X3 for audio of the third comparison example shown in FIG. 8, all of the wires 3 include Au, which is an example of the second metal, as the main component.

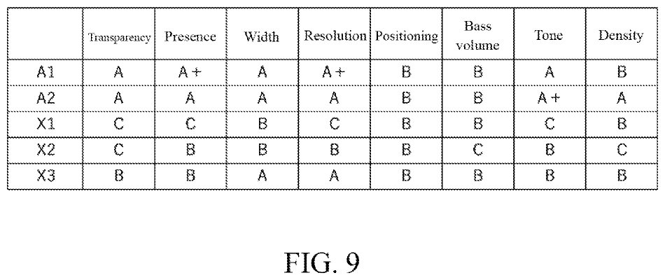

FIG. 9 shows results of sound quality evaluation of the semiconductor devices A1, A2, X1, X2 and X3 for audio. For example, evaluation indicators include “transparency”, “presence”, “width”, “resolution”, “positioning”, “bass volume”, “tone” an “density”. As for gradings for the items above, A+represents “exceptional”, A represents “outstanding”, B represents “good” and C represents “satisfactory”. However, sound quality evaluation may vary greatly depending on the subjective opinions of evaluators or preferences for sound quality of predetermined users. For example, for different evaluators, the gradings for items including “transparency”, “presence”, “width”, “resolution”, “positioning”, “bass volume”, “tone” and “density” may vary.

In the semiconductor devices A1, A2 and X2 for audio, the plurality of wires 3 include the first wires and the second wires. As a result, comparing the semiconductor device X1 for audio in which all of the plurality of wires 3 are the first wires and the semiconductor device X3 for audio in which all of the plurality of wires 3 are the second wires, gradings of individual evaluation indicators shown in FIG. 9 are different. Thus, by appropriately setting the first wires and the second wires included in the plurality of wires 3, gradings of sound quality can be improved according to various conditions such as subjective opinions of the evaluators or preferences of the users.

The semiconductor devices A1 and A2 for audio achieve higher gradings in overall items in comparison with the semiconductor devices X1, X2 and X3 for audio. In the semiconductor devices A1 and A2 for audio, the plurality of wires 31 connected to the first electrodes 11 for digital signal inputs and the first electrodes 11 for digital power supplies among the plurality of first electrodes 11 are set as the first wires. Moreover, the plurality of wires 32 connected to the second electrodes 12 for analog signal outputs among the plurality of second electrodes 12 are set as the second wires. It is considered that such configuration is conducive to improving the gradings of the semiconductor devices A1 and A2 for audio. Among the plurality of first electrodes 11, the plurality of wires 31 connected to the first electrode 11 for digital signal input and the first electrode 11 for electromagnetic power supply are the first wires. This is because the main component is the first metal (Cu (copper) in this embodiment) and has a low electrical resistivity. Moreover, it is considered that the plurality of wires 32 connected to the second electrodes 12 for analog signal outputs among the plurality of second electrodes 12 help these wires 32 to include the second metal (Au in this embodiment) which is softer as the main component

Moreover, comparing the evaluation indicators of the semiconductor device A1 for audio and the semiconductor device A2 for audio, the semiconductor device A1 for audio achieves more exceptional gradings. In the semiconductor device A1 for audio, the plurality of first electrodes 11 connected to the third electrodes 13 for analog power supplies among the plurality of first electrodes 11 are set as the first wires. Moreover, in the semiconductor device A1 for audio, the plurality of wires 33 connected to the plurality of third electrodes 13 are set as the second wires. It is considered that the configuration above are conducive to achieving exceptional gradings for the evaluation indicators of “presence” and “resolution”.

Moreover, in substitution, the first wires can be configured to include the first metal as the main component, the second wires can be configured to include the second metal as the main component, and the following method is used. For example, the line diameters of the first wires can be configured to be thicker than those of the second wires. In this case, a configuration in which the electrical resistivity of the first wires is less than that of the second wires can be formed. Moreover, the second wires can be configured to be softer than the first wires. Alternatively, the first wires can be configured to be shorter than the second wires. In this case, a configuration in which the electrical resistivity of the first wires is less than that of the second wires can be formed. Moreover, the second wires can be configured to be softer than the first wires.

As described above, according to the audio semiconductor device according to the present disclosure, evaluation indicators related to audio applications can be improved.

The semiconductor device for audio of the present disclosure is not limited to the embodiments described above. Various design modifications may be made as desired to the specific structures of the components of the semiconductor device for audio of the present disclosure.
[Note 1]

A semiconductor device for audio, comprising:
a semiconductor element, including a plurality of electrodes;
a plurality of leads; and
a plurality of wires, electrically connecting the plurality of electrodes to the plurality of leads, wherein the plurality of wires include:
   a first wire, having a main component of a first metal; and
   a second wire, having a main component of a second metal different from the first metal.
[Note 2]

The semiconductor device for audio of Note 1, wherein the second metal is softer than the first metal.
[Note 3]

The semiconductor device for audio of Note 1 or 2, wherein the first metal has an electrical resistivity less than an electrical resistivity of the second metal.
[Note 4]

The semiconductor device for audio of any one of Notes 1 to 3, wherein the first metal is copper (Cu).
[Note 5]

The semiconductor device for audio of any one of Notes 1 to 4, wherein the second metal is aluminum (Al).
[Note 6]

The semiconductor device for audio of any one of Notes 1 to 5, wherein the first wire and the second wire have same wire diameter.
[Note 7]

A semiconductor device for audio, comprising:
a semiconductor element, including a plurality of electrodes;
a plurality of leads; and
a plurality of wires, electrically connecting the plurality of electrodes to the plurality of leads, wherein the plurality of wires include a first wire and a second wire, and the first wire has a wire diameter greater than a wire diameter of the second wire.
[Note 8]

A semiconductor device for audio, comprising:
a semiconductor element, including a plurality of electrodes;
a plurality of leads; and
a plurality of wires, electrically connecting the plurality of electrodes to the plurality of leads, wherein the plurality of wires include a first wire and a second wire, and the first wire is shorter than the second wire.
[Note 9]

The semiconductor device for audio of any one of Notes 1 to 8, wherein the semiconductor element has a quadrilateral shape in a plan view.
[Note 10]

The semiconductor device for audio of Note 9, wherein the plurality of leads are arranged to surround the semiconductor element along four sides of the semiconductor element in the plan view.
[Note 11]

The semiconductor device for audio of any one of Notes 1 to 10, wherein the semiconductor element is configured as an audio D/A converter.
[Note 12]

The semiconductor device for audio of Note 11, wherein
the plurality of electrodes include the electrode for digital signal input, and
the plurality of wires include the first wire connected to the electrode for digital signal input.
[Note 13]

The semiconductor device for audio of Note 12, wherein
the plurality of electrodes include the electrode for digital power supply, and
the plurality of wires include the first wire connected to the electrode for digital power supply.
[Note 14]

The semiconductor device for audio of Note 12 or 13, wherein
the plurality of electrodes include the electrode for analog signal output, and
the plurality of wires include the second wire connected to the electrode for analog signal output.
[Note 15]

The semiconductor device for audio of Note 14, wherein
the plurality of electrodes include the electrode for analog power supply, and
the plurality of wires include the first wire connected to the electrode for analog power supply.

1. A semiconductor device for audio, comprising:
a semiconductor element, including a plurality of electrodes;
a plurality of leads; and
a plurality of wires, electrically connecting the plurality of electrodes to the plurality of leads, wherein the plurality of wires include:
a first wire, having a main component of a first metal; and
a second wire, having a main component of a second metal different from the first metal.

2. The semiconductor device for audio of claim 1, wherein the second metal is softer than the first metal.

3. The semiconductor device for audio of claim 1, wherein the first metal has an electrical resistivity less than an electrical resistivity of the second metal.

4. The semiconductor device for audio of claim 1, wherein the first metal is copper (Cu).

5. The semiconductor device for audio of claim 1, wherein the second metal is aluminum (Al).

6. The semiconductor device for audio of claim 1, wherein the first wire and the second wire have same wire diameter.

7. A semiconductor device for audio, comprising:
a semiconductor element, including a plurality of electrodes;
a plurality of leads; and
a plurality of wires, electrically connecting the plurality of electrodes to the plurality of leads, wherein the plurality of wires include a first wire and a second wire, and the first wire has a wire diameter greater than a wire diameter of the second wire.

8. A semiconductor device for audio, comprising:
a semiconductor element, including a plurality of electrodes;
a plurality of leads; and
a plurality of wires, electrically connecting the plurality of electrodes to the plurality of leads, wherein the plurality of wires include a first wire and a second wire, and the first wire is shorter than the second wire.

9. The semiconductor device for audio of claim 1, wherein the semiconductor element has a quadrilateral shape in a plan view.

10. The semiconductor device for audio of claim 9, wherein the plurality of leads are arranged to surround the semiconductor element along four sides of the semiconductor element in the plan view.

11. The semiconductor device for audio of claim 1, wherein the semiconductor element is configured as an audio D/A converter.

12. The semiconductor device for audio of claim 11, wherein
the plurality of electrodes include the electrode for digital signal input, and
the plurality of wires include the first wire connected to the electrode for digital signal input.

13. The semiconductor device for audio of claim 12, wherein
the plurality of electrodes include the electrode for digital power supply, and
the plurality of wires include the first wire connected to the electrode for digital power supply.

14. The semiconductor device for audio of claim 12, wherein
the plurality of electrodes include the electrode for analog signal output, and
the plurality of wires include the second wire connected to the electrode for analog signal output.

15. The semiconductor device for audio of claim 14, wherein
the plurality of electrodes include the electrode for analog power supply, and
the plurality of wires include the first wire connected to the electrode for analog power supply.
